(19) United States
(12) Patent Application Publication
(10) Pub. No.: US 2010/0116206 A1
(43) Pub. Date: May 13, 2010

(54) GAS DELIVERY SYSTEM HAVING REDUCED PRESSURE VARIATION

(75) Inventor: KEDARNATH S. SANGAM, Sunnyvale, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 12/270,678

(22) Filed: Nov. 13, 2008

(51) Int. Cl. C23C 16/455

(52) U.S. Cl. 118/715

(57) ABSTRACT

Embodiments of gas delivery systems for providing process gases sublimated from a solid precursor are provided herein. In some embodiments, a gas delivery system includes an ampoule to hold a solid precursor; a conduit coupled to the ampoule and configured to selectively deliver a sublimated process gas from the solid precursor to a process chamber or an exhaust system; and a flow restrictor disposed in the conduit between the ampoule and the exhaust system.

### FIELD

Embodiments of the present invention generally relate to semiconductor processing equipment and more particularly, to gas delivery systems for such processing equipment.

### BACKGROUND

Fabrication of semiconductor devices involves growing thin films on a substrate. Several variants of CVD processes, including Atomic Layer Deposition (ALD), are employed for growing thin films on the substrate. Typically in an ALD process, one or more monolayers can be successively deposited on the substrate to form a film of desired thickness. In some embodiments, a monolayer may be formed from a precursor. Such precursors can include low vapor pressure precursors, for example, hafnium tetrachloride (HfCl₄). A solid form of the precursor can be stored in an ampoule, and be sublimed into a carrier gas stream that is in fluid communication with the process chamber.

Due to the need to maintain high process throughput, the sublimed precursor is typically continuously flowed from the ampoule during an ALD process. For example, the precursor flowed from the ampoule may be provided to the process chamber when a monolayer of the precursor is deposited, and then closed to the process chamber and routed to an exhaust line or other location when a monolayer of a different precursor is being deposited on the substrate or other process gas is being flowed to the process chamber. During the period when the ampoule is closed to the process chamber, the precursor continues to flow into the exhaust system. Unfortunately, the large pressure differential between the chamber pressure and the exhaust system pressure results in large pressure swings inside the ampoule. Such pressure swings can result in differences in precursor concentration within the carrier gas stream, and consequently differences in the quantity of precursor delivered to the substrate in successive pulses of the precursor. In addition, the pressure swings can, under some conditions, cause a reverse flow from the exhaust to the ampoule, which will undesirably contaminate the pure chemical in the ampoule.

Thus, there is need in the art for an improved chemical delivery system.

### SUMMARY

Embodiments of gas delivery systems for providing process gases sublimated from a solid precursor are provided herein. In some embodiments, a gas delivery system includes an ampoule to hold a solid precursor; a conduit coupled to the ampoule and configured to selectively deliver a sublimated process gas from the solid precursor to a process chamber or an exhaust system; and a flow restrictor disposed in the conduit between the ampoule and the exhaust system.

In some embodiments, an apparatus for processing a substrate includes a process chamber; an exhaust system coupled to the process chamber; and a gas delivery system coupled to the process chamber and the exhaust system, the gas delivery system including an ampoule to hold a solid precursor; a conduit coupled to the ampoule and configured to selectively deliver a sublimated process gas from the solid precursor to a process chamber or an exhaust system; and a flow restrictor disposed in the conduit between the ampoule and the exhaust system. Other and further embodiments of the present invention are described below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a process chamber in accordance with some embodiments of the present invention.

FIG. 2 is a schematic cross-sectional view of a flow restrictor in accordance with some embodiments of the present invention.

To facilitate understanding, identical reference numerals have been used, where possible, to designate identical elements that are common to the figures. The above drawings are not to scale and may be simplified for illustrative purposes.

### DETAILED DESCRIPTION

Embodiments of gas delivery systems for providing process gases sublimated from a solid precursor are provided herein. The gas delivery system includes an ampoule for holding a solid precursor coupled to a conduit for selectively delivering a sublimated process gas from the solid precursor to a process chamber or an exhaust system, and a flow restrictor disposed in the conduit between the ampoule and the exhaust system. The flow restrictor advantageously reduces pressure swings in the ampoule when the flow from the ampoule is switched between the process chamber and the exhaust system. Thus, the gas delivery system advantageously facilitates delivery of consistent quantities of the gaseous precursor, for example, during successive pulses of the precursor in an atomic layer deposition (ALD) process. In addition to minimizing the pressure swings, the flow restrictor further prevents back streaming of exhaust gases from the exhaust area to the ampoule by establishing a pressure gradient between the ampoule and the exhaust that does not favor back streaming.

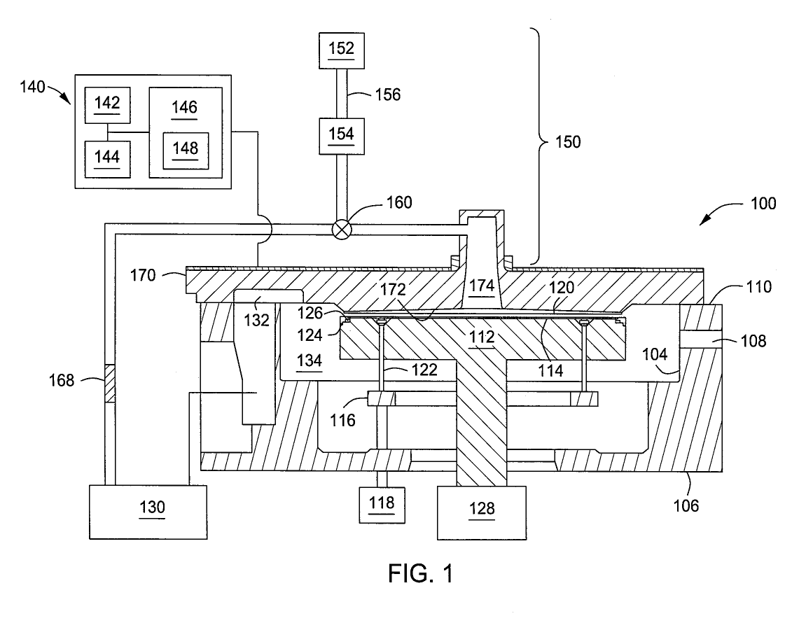

The inventive gas delivery system may be implemented in any apparatus where selective delivery of a sublimated process gas is provided. However, one particular apparatus where the inventive gas delivery system may be beneficially incorporated is an ALD apparatus. FIG. 1 is a schematic cross-sectional view of an exemplary ALD apparatus. The ALD apparatus comprises a process chamber 100 and a gas delivery system 150. The gas delivery system 150 is adapted for cyclic deposition, such as Atomic Layer Deposition or Rapid Chemical Vapor Deposition. The process chamber 100 may also be adapted for other deposition techniques.

The process chamber 100 comprises a chamber body 110 having side walls 104 and a base 106. A slit valve 108 in the process chamber 100 provides access for a robot (not shown) to deliver and retrieve a substrate 120, such as a semiconductor wafer. In some embodiments, the semiconductor wafer has a diameter of 200 mm or 300 mm. The details of exemplary process chamber 100 are described in commonly assigned United States Patent Application Publication No. 2005-0271813, filed on May 12, 2005, entitled “Apparatuses and Methods for Atomic Layer Deposition of Hafnium-Containing High-K Dielectric Materials,” and United States Patent Application Publication No. 2003-0079686, filed on Dec. 21, 2001, entitled “Gas Delivery Apparatus and Method for Atomic Layer Deposition,” which are both incorporated herein in their entirety by references. Two exemplary chambers suitable for use with the inventive gas delivery system may include GEMINI ALD or CVD chambers available from Applied Materials, Inc.

A substrate support 112 supports the substrate 120 on a substrate receiving surface 114. The substrate support (or pedestal) 112 is mounted to a lift motor 128 to raise or lower the substrate support 112 and a substrate 120 disposed thereon. A lift plate 116 coupled to a lift motor 118 is mounted in the process chamber 100 and raises or lowers pins 122 movably disposed through the substrate support 112. The pins 122 raise or lower the substrate 120 over the surface of the substrate support 112. In some embodiments, the substrate support 112 includes a vacuum chuck, an electrostatic chuck, or a clamp ring for securing the substrate 120 to the substrate support 112.

The substrate support 112 is heated to increase the temperature of the substrate 120 disposed thereon. For example, the substrate support 112 may be heated using an embedded heating element, such as a resistive heater or may be heated using radiant heat, such as heating lamps disposed above the substrate support 112. A purge ring 124 is disposed on the substrate support 112 to define a purge channel 126 which provides a purge gas to a peripheral portion of the substrate 120 to prevent deposition thereon.

An exhaust system 130 is in communication with a pumping channel 132 to evacuate any undesirable gases from the process chamber 100. The exhaust system 130 also helps in maintaining a desired pressure or a desired pressure range inside the process chamber 100.

The gas delivery system 150 is coupled to the chamber body 110 to provide precursor(s) and/or purge gases to the process chamber 100. The gas delivery system 150 includes an ampoule 154 and a conduit 156. The conduit 156 couples the ampoule 154 to both the process chamber 100 and the exhaust system 130. A switching valve 160 disposed in the conduit 156 is provided and configured to selectively divert flow from the ampoule 154 to the process chamber 100 or to the exhaust system 130. A flow restrictor 168 is disposed in the conduit 156 between the switching valve 160 and the exhaust system 130. A carrier gas source 152 is coupled to conduit 156 upstream of the ampoule 154. A carrier gas flown from the carrier gas supply 152 is utilized to transport sublimed precursor held within the ampoule 154 to the process chamber 100 or to the exhaust system 130.

The ampoule 154 is configured to hold a solid precursor, which may be sublimed into gaseous form. In some embodiments, the rate of sublimation of the solid precursor may be increased by, for example, heating the ampoule. Exemplary precursors may include low vapor pressure precursors such as hafnium tetrachloride (HfCl₄), although other precursors may be utilized. The ampoule may be of any suitable shape, for example, rectangular, non-rectangular, spherical, polyhedric, or the like. The ampoule may be of any suitable cross-section, for example, tapered, rectangular, or the like. In some embodiments, the shape and/or cross section of the ampoule may be selected to maximize surface to volume ratio in the ampoule. For example, high surface to volume ratio may be beneficial for maximizing heat transfer to the surface of the ampoule and the solid precursor within. Suitable methods for providing heat to the ampoule include providing heating elements, such as heating pads, proximate to or at least partially covering the surface of the ampoule, or the like.

The switching valve 160 is disposed in the conduit 156 and facilitates the coupling of the ampoule 154 to both the process chamber 100 and exhaust system 130. The switching valve 160 is configured to selectively open the ampoule 154 to the process chamber 100 or the exhaust system 130. The switching valve 160 may be any suitable valve, for example, a three-way valve or the like.

For example, during a deposition process, or a portion of a cycle of an ALD process (e.g., when the precursor is desired to be delivered to the process chamber), the switching valve 160 may route the flow from the ampoule 154 to the process chamber 100, allowing sublimed precursor and carrier gas to flow through the conduit 156 and into the process chamber 100. In the process chamber depicted in FIG. 1, the process gases may flow into an expanding channel 174 disposed in a lid 170 of the process chamber 100. From the expanding channel 174, the sublimed precursor and carrier gas may be delivered to the substrate 120.

When flow of the precursor is not desired to be delivered to the process chamber, such as during a purge of the process chamber 100, or the deposition of another precursor and/or process gas (which may be provided by a similar gas delivery apparatus), the switching valve 160 may route the flow from the ampoule 154 to the exhaust system 130. As such, flow of the sublimed precursor and the carrier gas is not stopped, but rather is maintained and routed from the ampoule 154 to the exhaust system 130. The flow restrictor 168 disposed within the conduit 156 between the switching valve 160 and the exhaust system 130 provides a restriction in the conduit 156 that facilitates maintaining a high pressure in the conduit 156, while preventing back-streaming of exhaust gases. Thus, the flow restrictor 168 protects the ampoule 154 from exposure to the reduced pressure of the exhaust system 130, thereby preventing loss of pressure in the ampoule 154, which undesirably impacts the rate of sublimation and the concentration of the precursor present in the carrier gas.

In some embodiments, the flow restrictor 168 is configured to maintain a substantially constant pressure in the ampoule when flow from the ampoule is switched from the process chamber 100 to the exhaust system 130. In some embodiments, the pressure change in the ampoule 154 during the switching between the process chamber 100 and the exhaust system 130 is between about 10 to about 20 Torr. If the flow restrictor 168 is not sized properly, the pressure can go up or down. To avoid pressure swings within the ampoule 154, the flow impedances of the two paths between the ampoule 154 and the exhaust system 130 are the same (e.g., the path through the process chamber 100 and the path through the flow restrictor 168). Sizing the flow restrictor 168 for the range of expected flow rates can facilitate impedance matching between the two paths.

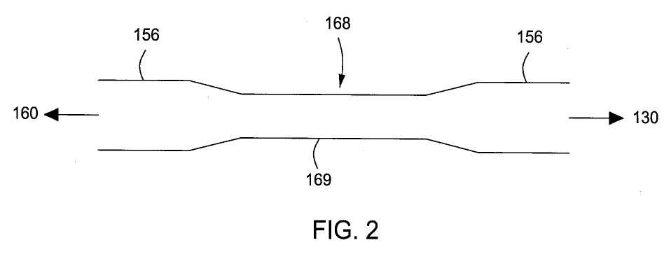

The flow restrictor 168 may be any suitable device for restricting flow in the conduit 156 such that the pressure drop with the ampoule 154 is maintained with the tolerances specified above. One exemplary embodiment of the flow restrictor 168 is shown in FIG. 2, where the flow restrictor 168 includes a reduced diameter portion of the conduit 156. The flow restrictor 168 facilitates a higher pressure in the conduit 156 by restricting flow through the reduced diameter portion (e.g., constricting orifice 169) of the flow restrictor 168. For example, in one non-limiting illustrative embodiment, the diameter of the conduit 156 may be about 3 mm or above and the diameter of the constricting orifice may be between about 0.5 and about 1.5 mm millimeters, or about 1.0 millimeters.

Returning to FIG. 1, at least a portion of a bottom surface 172 of a chamber lid 170 may be tapered from the expanding channel 174 to a peripheral portion of the chamber lid 170. The expanding channel 174 improves velocity profile of gas flow from the expanding channel 174 across the surface of the substrate 120 (i.e., from the center of the substrate to the edge of the substrate). In some embodiments, the bottom surface 172 comprises one or more tapered surfaces, such as a straight surface, a concave surface, a convex surface, or combinations thereof. In one preferred embodiment, the bottom surface 172 is tapered in the shape of a funnel. The expanding channel 174 is one exemplary embodiment of a of a gas inlet for delivering the sublimed precursor and carrier gas from the conduit 156 to the substrate 120. Other gas inlets are possible, for example, a funnel, a non-tapering channel, nozzles, showerheads, or the like.

In some embodiments, the process chamber 100 may be adapted to receive multiple precursors either simultaneously or individually through multiple carrier gas lines. Only one representative conduit 156 is shown in FIG. 1. Further disclosure of a process chamber adapted to receive multiple gas flows is described in previously incorporated United States Patent Application Publication No. 2003-0079686.

A controller 140, such as a programmed personal computer, work station computer, or the like is coupled to the process chamber 100. Illustratively, the controller 140 comprises a Central Processing Unit (CPU) 142, support circuitry 144, and a memory 146 containing associated control software 148. The controller 140 controls the operating conditions of processes performed in the process chamber, such as, for example, an ALD process. For example, the controller 140 may be configured to control the flow of various precursor gases and purge gases from gas sources to the process chamber or the exhaust system during different stages of the deposition cycle.

In operation, and referring to FIG. 1, a carrier gas is provided by the carrier gas source 152. The carrier gas may be any suitable carrier gas for carrying the sublimed precursor. In some embodiments, the carrier gas is at least one of nitrogen, argon, or the like. The carrier gas is flowed from the carrier gas source 152 to the ampoule 154, where it intermixes with sublimed precursor. The ampoule 154 may be heated as described above to assist in subliming sufficient quantity of the solid precursor held within the ampoule 154. The heating methods may be sufficient to create a vapor pressure of the precursor within the ampoule between about 0.1 to 2 Torr. In one embodiment, a hafnium tetrachloride precursor is heated at about 135 degrees Celsius to generate a vapor pressure of about 0.1 Torr. The sublimed precursor is swept into the conduit 156 by the carrier gas flowing through the ampoule 154.

From the ampoule 154, a gaseous mixture of the carrier gas and sublimed precursor can be carried to either the process chamber 100 or the exhaust system 130 via the switching valve 160. For example, the switching valve may first be positioned to route the gaseous mixture to the process chamber during a first portion of a process to facilitate deposition of materials on the substrate 120. In some embodiments, a monolayer, or a thin layer, of the precursor may be deposited on the substrate 120 while the ampoule 154 is open to the process chamber 100. In some embodiments, the pressure in the ampoule 154 may be between about 10 to 20 Torr, when the flow from the ampoule 154 is routed to the process chamber 100.

Next, for example, after one pulse of an ALD process, the switching valve 160 closes the ampoule 154 to the process chamber 100 and opens the ampoule to the exhaust system 130 (e.g., routes the flow from the ampoule to the exhaust system). Here, and in the absence of pressure control, such as that provided by the flow restrictor 168, a substantial pressure drop would occur in the ampoule 154 because the ampoule 154 would be exposed to the reduced pressure of the exhaust system 130, which is substantially lower than the pressure in the process chamber. In some embodiments, the pressure differential between the process chamber 100 and the exhaust system 130 are between about 0.5 to 3 Torr. Such a pressure drop could facilitate a higher concentration of sublimed precursor in the gaseous mixture, and thus a subsequent pulse of the gas mixture to the substrate 120 could, for example, form a thicker layer of the precursor, which may be undesirable.

To avert large swings in concentration of the precursor within the gaseous mixture when the ampoule 154 is switched from the process chamber 100 to the exhaust system 130, the flow restrictor 168 is disposed in the conduit 156 as discussed above. The presence of the flow restrictor 168 ensures that the flow velocity of the gaseous mixture through the conduit 156 is greater than the flow of the gaseous mixture through the constricting orifice 169 of the flow restrictor 168, and thus a higher pressure is maintained in the ampoule 154. In some embodiments, the flow restrictor 168 is appropriately sized within respect to the conduit 156 such that the pressure in the ampoule 154 is maintained between about 10 to 20 Torr, when the pressure in the exhaust system 130 is between about 0 to 0.5 Torr. As such, the presence of the flow restrictor 168 reduces pressure drops in the ampoule 154 when the ampoule 154 is switched between the process chamber 100 and the exhaust system 130.

Thus, improved gas delivery systems have been provided herein. The inventive gas delivery systems advantageously reduce pressure swings in an ampoule providing a sublimed precursor species when the ampoule is switched between the process chamber and the exhaust system. Thus, the gas delivery system advantageously delivers consistent quantities of the precursor, for example, during successive pulses of the precursor in an atomic layer deposition (ALD) process.

While the foregoing is directed to embodiments of the present invention, other and further embodiments of the invention may be devised without departing from the basic scope thereof.

1. A gas delivery system, comprising:
an ampoule to hold a solid precursor;
a conduit coupled to the ampoule and configured to selectively deliver a sublimated process gas from the solid precursor to a process chamber or an exhaust system; and
a flow restrictor disposed in the conduit between the ampoule and the exhaust system.

2. The gas delivery system of claim 1, further comprising a carrier gas source coupled to the ampoule and configured to flow a carrier gas therethrough.

3. The gas delivery system of claim 1, further comprising:
a switching valve disposed in the conduit between the ampoule and the flow restrictor to switch a gas flowing from the ampoule between the exhaust system and the process chamber.

4. The gas delivery system of claim 3, wherein the flow restrictor is configured to maintain a substantially constant pressure within the ampoule when the switching valve is switched from the process chamber to the exhaust system.

5. The gas delivery system of claim 1, wherein the flow restrictor comprises a constricted portion of the conduit.

6. The gas delivery system of claim 1, wherein the conduit has a diameter of at least about 3 mm.

7. The gas delivery system of claim 6, wherein the flow restrictor has a reduced diameter portion having a diameter of between about 0.5 and about 1.5 mm.

8. An apparatus for processing a substrate, comprising:
a process chamber;
an exhaust system coupled to the process chamber; and
a gas delivery system coupled to the process chamber and the exhaust system, the gas delivery system comprising:
an ampoule to hold a solid precursor;
a conduit coupled to the ampoule and configured to selectively deliver a sublimated process gas from the solid precursor to a process chamber or an exhaust system; and
a flow restrictor disposed in the conduit between the ampoule and the exhaust system.

9. The apparatus of claim 8, further comprising a carrier gas source coupled to the ampoule and configured to flow a carrier gas therethrough.

10. The apparatus of claim 8, further comprising:
a switching valve disposed in the conduit between the ampoule and the flow restrictor to switch a gas flowing from the ampoule between the exhaust system and the process chamber.

11. The apparatus of claim 8, wherein the flow restrictor is configured to maintain a substantially constant pressure within the ampoule when the switching valve is switched from the process chamber to the exhaust system.

12. The gas delivery system of claim 8, wherein the flow restrictor comprises a constricted portion of the conduit.

13. The gas delivery system of claim 8, wherein the conduit has a diameter of at least about 3 mm.

14. The gas delivery system of claim 8, wherein the flow restrictor has a reduced diameter portion having a diameter of between about 0.5 and about 1.5 mm.
